(19) United States
(12) Patent Application Publication
(10) Pub. No.: US 2021/0250107 A1
(43) Pub. Date: Aug. 12, 2021

(54) METHODS AND APPARATUSES FOR TESTING WIRELESS COMMUNICATION TO VEHICLES

(71) Applicant: RANLOS AB, Göteborg (SE)

(72) Inventor: Per-Simon KILDAL, Pixbo (SE)

(73) Assignee: RANLOS AB, Göteborg (SE)

(21) Appl. No.: 17/192,339

(22) Filed: Mar. 4, 2021

Related U.S. Application Data
(63) Continuation of application No. 15/113,641, filed on Jul. 22, 2016, now abandoned.

(30) Foreign Application Priority Data
Jan. 30, 2014 (EP) 14153281.2
Mar. 11, 2014 (EP) PCT/EP2014/054620

(51) Int. Cl. H04B 17/10; H04B 17/29; G01R 29/08; G01R 29/10

(52) U.S. Cl. CPC H04B 17/102; H04B 17/29; H04B 17/3912; G01R 29/105; G01R 29/0821

(57) ABSTRACT

An apparatus for measuring over-the-air (OTA) wireless communication performance in an automotive application of a device under test arranged on or in a vehicle. The apparatus includes a chamber and a platform for supporting the vehicle within the chamber. The platform is a rotatable platform that can rotate the vehicle, and the floor is inwardly reflective, and optionally covered with a top layer to resemble asphalt or other road covers. In one embodiment, the chamber is a reverberation chamber, simulating a multi-path environment, and preferably a rich isotropic multipath (RIMP) environment. In another embodiment, the chamber has inwardly absorbing walls, simulating a random-LOS environment.

### CROSS REFERENCE TO RELATED APPLICATIONS

The present application is a continuation of U.S. application Ser. No. 15/113,6641, filed on Jul. 22, 2016, which is a U.S. National Stage of International Application No. PCT/EP2014/074754, filed on Nov. 17, 2014, which claims the benefit of International Application No. PCT/EP2014/054620, filed on Mar. 11, 2014 and the benefit of European Application No. 14153281.2, filed on Jan. 30, 2014. The entire contents of each of U.S. application Ser. No. 15/113,6641, International Application No. PCT/EP2014/074754, International Application No. PCT/EP2014/054620, and European Application No. 14153281.2 are hereby incorporated herein by reference in their entirety.

### TECHNICAL FIELD

The present invention relates to a new compact and cost-effective test chamber/apparatus for wireless communication in automotive applications.

### BACKGROUND

The wireless communications grows, and the application areas increase. Most humans have today a smart phone, and more and more devices become connected to the internet via wireless communications. The newest digital communication systems like LTE or 4G are very advanced with both MIMO (Multiple Input Multiple Output) multiport antenna technology and OFDM (Orthogonal Frequency Domain Multiplexing). An important new market segment that will grow fast is wireless communications to cars, buses and other vehicles, hereinafter and commonly referred to as automotive applications. The purpose is often to entertain the passengers, but also to provide services that make it safer to drive the car. An important vision in that respect is to have driver-less vehicles on the roads several places of the world in a few years.

The growth of wireless communications allows more and more advanced devices and services, and this has increased the needs for testing them. In particular, it is important to test wireless devices and their applications in real-life situations, so-called drive tests. However, drive tests are very expensive, and therefore there is a need for related tests in real-life-like environments, often referred to as Over-The-Air (OTA) testing, in contrast to so-called “conducted” tests by connecting cables to the devices and thereby not including neither the environment nor the antennas.

The classical way to test antennas and wireless devices is in anechoic chambers. In anechoic chambers there is only one incident wave on the device under test (DUT). This is referred to as a Line-Of-Sight (LOS) and comes from a well-defined direction given by an Angle-of-Arrival (AoA). However, the real-life environment is normally a multipath environment with many incident waves, causing signal variations called fading due to interference between the waves. The most arbitrary fading appears when there are many waves and the user with his device moves in the multipath. This is referred to as Rayleigh fading.

A more recently developed way of testing is to use a reverberation chamber (RC). RCs have since 2000 been developed into an accurate and useful tool for performing OTA tests during Rayleigh fading. The tests included first only so-called passive measurements of antenna efficiency, and active measurements of radiated power (U.S. Pat. No. 7,444,264 by Kildal). The procedures were later extended to measure receiver sensitivity, both according to a similar procedure used in anechoic chambers, referred to as Total Isotropic Sensitivity (TIS), and during continuous fading, referred to as average fading sensitivity (U.S. Pat. No. 7,286,961 by Kildal). The accuracy of the OTA tests in RC has been further improved by an appropriate calibration routine, and several practical improvements (WO 12/171562 by Kildal & Orlenius).

The RC emulates a rich isotropic multipath (RIMP) if it is well stirred. This is what makes it possible to make repeatable and accurate measurements. However, the RC is not covering all real-life environments. To complete the test it is also, at least for some applications, important to cover the case when there is a dominant LOS contribution. This happens typically in these situations:
1. In an open landscape when the base station can be seen, such as at the countryside. This appears more often for automotive cases.
2. Inside normally large rooms where there is a so-called micro base station.
3. For wireless communication between machines, referred to as Machine to Machine (M2M).

The traditional anechoic chamber can be used for testing under LOS conditions. However, the anechoic test techniques have only been developed for testing of antenna systems with narrow directive beams, and then there is required an accurate positioning of the antenna in the its installation, and therefore also under test. However, the modern wireless devices works without having a directive narrow beam of high quality pointing towards the base station. The reason is that the receivers in wireless devices are very sensitive. Therefore, the antennas on the modern wireless devices have rather wide radiation patterns. In fact, the radiation patterns are also very much affected by the user and his way of using the device, being referred to as user statistics. Therefore, the traditional anechoic test technologies are not appropriate for testing wireless devices when they are subject to LOS. There is instead a need to introduce new anechoic test environments. These new test environments can be made much cheaper than traditional ones because there is no longer any need for accuracy in the directional characteristics, because the AoA is random. Such a new anechoic test environment for testing wireless devices was introduced in P.-S. Kildal, C. Orlenius, J. Carlsson, “OTA Testing in Multipath of Antennas and Wireless Devices with MIMO and OFDM”, Proceedings of the IEEE, Vol. 100, No. 7, pp. 2145-2157, July 2012, and referred to as pure-LOS. This concept was further improved in P.-S. Kildal and J. Carlsson, “New Approach to OTA Testing: RIMP and pure-LOS as Extreme Environments & a Hypothesis”, in EuCAP 2013, Gothenburg, Sweden, 2013 by introducing the term random-LOS for the specific pure-LOS environment with a random AoA, and by introducing a real-life hypothesis that binds together the two edge environments RIMP and random-LOS.

The tests in RIMP and random-LOS environments are implemented as so-called throughput tests. The throughput can further easily be understood as a probability of detection, by means of the ideal so-called threshold receiver, see P. S. Kildal, A. Hussain, X. Chen, C. Orlenius, A. Skårbratt, J. Åsberg, T. Svensson, and T. Eriksson, “Threshold Receiver Model for Throughput of Wireless Devices with MIMO and Frequency Diversity Measured in Reverberation Chamber”, IEEE Antennas and Propagation Wireless Letters, vol. 10, pp. 1201-1204, October 2011.

By introducing the ideal threshold receiver it is possible to model in a simple and accurate way the effects of the MIMO and the OFDM, as seen in A. Hussain and P.-S. Kildal, “Study of OTA Throughput of 4G LTE Wireless Terminals for Different System Bandwidths and Coherence Bandwidths in Rich Isotropic Multipath”, in EuCAP 2013, Gothenburg, Sweden, 2013. Both MIMO and OFDM are implemented in modern wireless systems like LTE/4G to overcome the problems with the fading. Without MIMO and OFDM the interference dips due to the fading may cause levels that are too low to be detected. Therefore, the wireless devices are provided with multi-port antennas both for transmitting and receiving signals and combining the signals on the different ports in an optimum way, referred to as MIMO (Multiple Input Multiple Output) technology. This MIMO technology makes it possible to transmit a single data stream with much higher probability of detection (PoD) than before, because the problems of the fading are partly removed. The effect of the fading can be further improved by making use of another digital signal processing technology, the OFDM. The OFDM divides the signal in several subchannels, and combine these again on the receive side in an optimum way, referred to as Maximum Ratio Combining (MRC) or similar. There exist also other digital functions that improved performance. High quality testing of MIMO and OFDM functions has till now only been done in the RIMP emulated by a reverberation chambers.

LOS testing of vehicles is today done in very large and expensive anechoic chambers. There are available on the market also RCs for automotive EMC tests. However, these are also very large and expensive. Therefore there is a need for improved testing and measuring methods and apparatuses. Specifically, there is a need for more cost-efficient OTA chambers for testing wireless communications to vehicles, still having similar or even improved measurement quality than in the presently available systems.

### SUMMARY

It is therefore an object of the present invention to alleviate the above-discussed problems, and specifically to introduce a new compact and cost-effective test chamber/apparatus for automotive applications, for characterizing wireless communications, devices and equipment in both RIMP and random-LOS environments, and corresponding measurement/testing methods.

According to a first aspect of the invention there is provided an apparatus for measuring over-the-air (OTA) wireless communication performance in an automotive application of a device under test arranged on or in a vehicle, such as a car or a bus, comprising: a chamber defining an internal cavity therein, and a platform for supporting the vehicle, wherein the chamber is adapted to enclose the platform, wherein the platform is a rotatable platform that can rotate the vehicle, and wherein the floor of the chamber is inwardly reflective, and optionally covered with a top layer to resemble asphalt or other road covers.

The term “device under test” is in the context of this application used to indicate any type of device capable of transmitting or receiving electromagnetic signals through a wireless interface. In particular, the device under test can be mobile phones and other wireless terminals with antennas, and these devices or parts of them such as the antennas can be either be mounted to the vehicle, integrated with the vehicle, or carried by the users of the vehicles or its passengers.

The invention is based on the conviction that real-life environments for wireless communication with vehicles, such as cars and busses, are somewhere in between the edge environments of free space (pure-LOS) and rich isotropic multipath (RIMP). Free space (pure-LOS) may be measured in an anechoic chamber, whereas RIMP may be measured in a reverberation chamber (RC). Further, it is based on the conviction that if wireless terminals work well in RIMP and random pure-LOS environments, they will work well also in real-life environments. Thus, by efficient measurement of these edge environments, in test facilities, expensive drive tests may be reduced or even completely omitted. Rough estimates provide that for handheld smart phones and laptops in general situations, the relative importance of RIMP and random-LOS is approximately 80-90% for RIMP and 10-20% for random-LOS. For vehicles, the situation would be roughly the opposite, with approximately 20% for RIMP and 80% for random-LOS. Thus, the testing in random-LOS is much more important for automotive applications than for other general usages.

Still further, the present invention is based on the conviction that it is also possible to use PoD as a metric of performance in random-LOS environments. The present invention relates to a way of measuring PoD in random-LOS, which in particular is advantageous for automotive tests of complete vehicles such as cars, trucks and buses.

The present invention provides two very cost-efficient OTA chambers for testing wireless communications to vehicles, with one of the chambers adapted to and useable for testing in the RIMP environment and the other in random-LOS. However, they may also be combined in one chamber by using interchangeable parts. Further, by means of the present invention, similar or even improved measurement quality than in the presently available systems will be obtained.

The over-the-air (OTA) wireless communication performance measurable by means of the present invention is preferably one or several of the following: total radiated power (TRP), total isotropic sensitivity (TIS), throughput, antenna efficiency, average fading sensitivity, and diversity and MIMO gain. Antenna efficiency is here used as a measure of the efficiency with which an antenna converts the radio-frequency power accepted at its terminals into radiated power. Diversity and MIMO gain is here used as a measure of the improvement in PoD obtainable by using multiple antennas.

According to the present invention, the vehicle to be tested is located on a rotatable platform, which preferably can rotate the car 360°. The rotation may be controlled by a control PC, in same way as for the per se known platform stirring used in U.S. Pat. Nos. 7,444,264, 7,286,961 and WO 12/171562, said documents hereby being incorporated in their entirety by reference. The floor should be inwardly reflective, and e.g. be of metal, or of other conductive material(s), but the floor/metal can additionally be covered with something to resemble a top layer of asphalt or other road covers.

By rotation of the vehicle during measurement, either intermittently or continuously, it has been found that a very efficient stirring and mode distribution is obtained within the chamber.

Preferably, the platform has means to allow the vehicle to be measured with the wheels rolling and the engine working. Hereby, extra stirring will be provided, and also, the measurement will be made under even more realistic environmental conditions, thereby increasing the accuracy and quality of the measurements.

The platform is preferably arranged to be rotatable 360°, and to be rotated continuously or intermittently (i.e. stepwise) during the measurements.

The chamber may be intended for measurements of cars only, but may also be for measurement of busses and trucks, as well as other types of vehicles.

The car/vehicle, or a user inside it, is preferably provided with a device for wireless communication, such as for the LTE/4G system, or for another communication system such as WiFi, 3G, 2G, IEEE 802.11 b/g/n (WiFi), worldwide interoperability for microwave access (WiMAX). The device may also be mounted in or even integrated with the vehicle itself.

According to one group of embodiments, the chamber is a reverberation chamber (RC). The RC test chamber generally correspond in its structure, use and operation to the ones discussed in U.S. Pat. Nos. 7,444,264, 7,286,961 and WO 12/171562, each of said documents hereby being incorporated in their entirety by reference. The reverberation chamber preferably has walls of an inwardly reflective material, rendering the walls reflective to electromagnetic waves, thereby simulating a multi-path environment, and preferably a rich isotropic multipath (RIMP) environment; at least one chamber antenna arranged in the cavity; and a measuring instrument connected to the device under test and the chamber antenna, for measuring the transmission between them.

It is further preferred that the internal chamber formed in the chamber is completely shielded, having reflecting material, such as metal, on all walls and floor and ceiling.

The platform and the thereon-supported vehicle may function as the sole mechanical stirrer in the chamber. No plate stirrers are needed, since the car, bus or other vehicle will in itself work as a mechanical stirrer. Due to the size of the vehicle, it has been found by the present inventor that the stirring obtained by the rotation of the platform, and the vehicle thereon, provides such a high degree of stirring that no additional mode stirring would normally be required. Thus, the chamber may be free of any other mechanical stirrer. Thereby, both manufacturing and operation of the measurement apparatus are facilitated. However, optionally such additional mechanical stirrers may be used as well.

The apparatus may further comprise a shield, arranged to prevent a direct line-of-sight between a chamber antenna and the device under test, the shield preferably being of metal. The shield may e.g. be configured and arranged in a way similar to the shield discussed in WO 12/171562.

The antenna may be of a type having orthogonal faces, similar to the one disclosed in WO 12/171562. However, preferably the antenna is a butterfly antenna, e.g. similar to the one discussed in PCT/SE2013/051130. Using such or similar antennas provides a very useful polarization stirring, and also enables e.g. MIMO measurements.

According to another group of embodiments, the chamber is a random-LOS chamber, having inwardly absorbing walls. Preferably, the random-LOS chamber has absorbers on all walls, rendering the walls absorbing to electromagnetic waves, thereby simulating a random-LOS environment, at least one chamber antenna arranged in the cavity; and a measuring instrument connected to the device under test and the chamber antenna, for measuring the transmission between them. The Random-LOS chamber is to a large extent similar to or the same as in the previously discussed RC chamber, but with the exceptions that the Random-LOS chamber has absorbers on the walls, and that there is no shield around the chamber antenna, and that the chamber antenna is different. This chamber can be made approximately equally small, or only to a small extent larger (due to the absorbers), than the previously discussed RC chamber.

The chamber is preferably completely shielded, having reflecting material, such as metal, on all walls and floor and ceiling, and absorbers being provided on all or most reflecting walls and ceiling, but not on the floor. The floor is preferably of metal (or conductive), but the metal can be covered with something to resemble a top layer of asphalt or other road covers.

Further, a chamber antenna/measurement antenna is preferably arranged in the chamber, and is preferably arranged as a vertical linear array antenna. The vertical linear array antenna may be dual-polarized, or there may be two such linear antennas located side-by-side, one for each of two orthogonal polarizations. The vertical linear array(s) may be arranged in one corner of the chamber or along a wall of the chamber.

The apparatus further preferably comprises a branched distribution/combination network, connecting the multiple ports of the vertical linear array antenna to a single port on the base station emulator. Thus, the output of the branched distribution network may be connected to a digital communication test instrument functioning as a base station emulator. There may also be an electronic so-called channel emulator between the base station emulator and the base station, providing the opportunity to vary the time delay spread during the measurements.

The linear array preferably comprises a plurality of wideband array elements. When the wireless device in the car is transmitting, its far field, being of course strongly affected by the vehicle itself, is to a good approximation given by the signal level of the single output of the branched distribution/combination network. Therefore, different far field directions in azimuth plane may be obtained by rotating the car, and thereby a complete radiation pattern in the horizontal plane is obtained. Further, the linear array may be tilted to obtain different elevation angles of the radiation patterns. Two orthogonally polarized vertical linear arrays will provide orthogonally polarized radiation patterns.

Alternatively, a pill-box style antenna can be used. This antenna comprises two parallel plates, a curved reflecting wall between the two plates, and an elongated aperture arranged opposite to the curved wall. The elongated aperture may be arranged between the side planes, i.e. emitting or receiving radiation in a main direction essentially parallel to the plates. However, alternatively, the elongate aperture may be arranged in one of the plates, or in an extension thereof, i.e. emitting radiation in a main direction being essentially perpendicular to this plate. A feeding or reception device, such as a dipole antenna, a feed horn or the like, may be arranged to emit radiation into the cavity between the side planes, and towards the curved reflector, and/or receive radiation reflected by said curved reflector. The reflector is preferably curved in the shape of a parabolic arc, so that the radiation from the feeding device will provide a field distribution over the elongated aperture with constant phase.

It is important to emphasize that the above radiation patterns do not need to be very accurate in the classical sense, because the purpose is here to characterize MIMO performance in random-LOS. E.g., there is now no requirement to the sense of the polarizations of the two linear arrays only that they are orthogonal. Further, there is no need to know very accurately the angle of the far field and the low sidelobe levels. However, preferably the cumulative distribution function of the received signal power within the desired angular range is correct, and only to a 95-99% level of the PoD. The PoD is the probability of having a received signal higher than the detection threshold of the base station emulator, so that 95% PoD means that 95% of the levels within the desired angular range are above the detection threshold. The PoD is a function of the transmitted power level. The above explanation is done when the wireless device is transmitting, but the explanation will be similar for the receiving case due to reciprocity. The above explanation also only considers one signal level, i.e. reception of one bit stream, whereas in MIMO systems we may transmit up to 2 bit streams with co-located MIMO antenna ports in pure-LOS. Therefore, a distinction is preferably made when measuring between the PoD of receiving one bit stream and two bit streams. The base station emulator will automatically measure throughput, which is the same as the PoD over angular variation range defined by the platform and the tilt of the linear array antennas. The above discussion is therefore only used to explain why the measured PoD in the present random-LOS setup is representative for measuring in the far field of the antenna on the car. The desired angular range of the measurements are typically 0° to 360° in azimuth, and 0° to 30° in elevation. The vertical direction of 90° elevation and close to it is not of interest for automotive applications. That is the reason why it is here possible to measure with only a linear array antenna not covering the directions above the car.

Both the above-discussed test chambers may be made very small compared to presently available anechoic chambers and RC chambers for measurement on vehicles, but with the same or improved accuracy of the measurements in terms of throughput/PoD. Specifically, the now proposed random-LOS chamber can emulate base stations at far-away distances, test MIMO under random-LOS, need not consider accuracy in position angle, produces CDF (Cumulative Distribution Function) in random-LOS for low elevation angles, and do not need accurate sidelobes and so on. Similarly, the new RC chamber does not need stirrers, since the stirring obtained by the vehicle (car) would normally be sufficient, polarization stirring would be good (for MIMO) and LOS-shields around the chamber antenna would be advantageous.

The height, length and width of the chamber can be very small compared to previously known chambers. Previously known anechoic test chambers for measurement of cars would typically require a chamber size of 25 m length, 15 m width and 10 m height. As a comparison, a random-LOS chamber of the present invention would for the same situation typically have a size of 7 m length, 7 m width and 2.5 m height. Similarly, a measurement chamber for a bus would previously be of a size of e.g. 30 m length, 20 m width and 15 m height, whereas with the present invention, the size may be reduced e.g. to 16 m length, 16 m width and 4.6 m height.

The height of the internal cavity of the chamber may be in the range of H+0.5 m and H+3 m, where H is the height of the highest vehicle on which the chamber is intended to measure (when it is located on the rotatable platform). For example, the height may be as low as only vehicle (car) height+1 m or more. A lower height makes the chamber less expensive.

The length and width of the internal cavity of the chamber may both be in the range of L+1.5 m and L+4 m, where L is the length of the longest vehicle (or width of the vehicle, should that be greater) on which the chamber is intended to measure. Typically, the room floor dimension is in both dimensions typically 2 m longer than the vehicle (car), but it can also be longer than 2 m. When 2 m longer, the wall of the chamber will everywhere be more than 1 m away from any part of the vehicle. Reduced horizontal dimensions make the chamber less expensive.

The apparatus further preferably comprises at least one linear array antenna within the chamber. Such a solution is, as already discussed, particularly suitable for random LOS chambers.

At least one of the linear array antennas may comprise several linear array sections arranged on top of each other. The several linear array sections may then be arranged in a straight disposition. However, the several linear array sections may alternatively be arranged in a curved disposition, extending from the base in a direction towards the platform, and preferably extending at least partly over the platform. Hereby, the linear array antenna will be curved into, and possibly also to some extent over, the vehicle on the platform. Hereby, more efficient measurements and simulations can be obtained, and the chamber can be made even more compact.

When two or more linear array antennas are provided, said linear array antennas may be distributed around the platform. It is for example possible to use, two, three, four or more columns of linear array antennas. The linear array antennas are preferably located at one side of the platform, e.g. along a straight line in the vicinity of the chamber wall, or along an arc or semicircle at a side of the platform, together forming a two-dimensional array, but they can also be distributed around the whole platform.

The apparatus further preferably comprises a distribution network for feeding the linear array.

When the linear array antenna comprises several sections, arranged in a curved disposition, the distribution network preferably comprises fixed delay lines compensation for the non-straight extension of the linear array, preferably in such a way that the voltage received at the end of the distribution network is representative of a far-field radiation pattern of the antenna when embedded on the platform.

The linear array antenna(s) may preferably be slightly tilted toward the platform to provide different elevation angles of the far field.

When at least two linear array antennas are provided, said linear array antennas are further preferably connected together with distribution networks in such a way that the common output port represents a quantity that is proportional to the far field of the antennas system on the car in one azimuthal direction (depending on angle of the platform on which the vehicle is located) and elevation direction (depending on the tilt angle of the arrays towards the vehicle). However, the linear arrays may also be connected to separate channel emulators, or to different ports on a common channel emulator. In this case the at least two linear array antennas are distributed around the platform and are also preferably individually calibrated.

When at least two linear array antennas are provided, the linear array antennas can also be located at different azimuth angles around the platform. Hereby, it becomes possible to emulate different angles of arrivals in the horizontal plane, due to large scattering objects, or to emulate connections with several base stations located at different azimuth angles around the vehicle.

According to another aspect of the present invention, there is provided a method for measuring over-the-air (OTA) wireless communication performance in an automotive application of a device under test arranged on or in a vehicle, comprising:

providing a chamber defining an internal cavity therein;

arranging the vehicle within the internal cavity; and

measuring over-the-air wireless communication performance while horizontally rotating the vehicle intermittently (i.e. stepwise) or continuously during the measuring.

Hereby, similar embodiments and advantages as discussed above are feasible.

The method further preferably comprises operating the vehicle so that the wheels are rolling and the engine is working during said measuring.

Further, the vehicle is preferably rotated over 360° during measurement.

The chamber may either be a reverberation chamber, thereby simulating a multi-path environment, and preferably a rich isotropic multipath (RIMP) environment, or a random-LOS chamber, having inwardly absorbing walls.

These and other features and advantages of the present invention will in the following be further clarified with reference to the embodiments described hereinafter.

### BRIEF DESCRIPTION OF THE DRAWINGS

For exemplifying purposes, the invention will be described in closer detail in the following with reference to embodiments thereof illustrated in the attached drawings, wherein:

FIG. 1 is a perspective side view showing the interior of a reverberation chamber apparatus in accordance with one embodiment of the present invention;

FIG. 2 is a perspective side view showing the interior of a random-LOS chamber apparatus in accordance with another embodiment of the present invention;

FIG. 3 is a schematic illustration of an exemplary antenna and distribution arrangement to be used in the apparatus of FIG. 2;

FIG. 4 is an alternative embodiment of an antenna useable in the apparatus of FIG. 2;

FIG. 5 is another alternative embodiment of an antenna useable in the apparatus of FIG. 2;

FIG. 6a-6c are top views, schematically illustrating various embodiments in which several linear array antennas are distributed around the platform, at on one or several side(s) of the vehicle/platform; and

FIG. 7a-7c schematically illustrate various arrangements of a linear array antenna comprising multiple sections.

### DETAILED DESCRIPTION OF PREFERRED EMBODIMENTS

In the following detailed description, preferred embodiments of the present invention will be described. However, it is to be understood that features of the different embodiments are exchangeable between the embodiments and may be combined in different ways, unless anything else is specifically indicated. Even though in the following description, numerous specific details are set forth to provide a more thorough understanding of e present invention, it will be apparent to one skilled in the art that the present invention may be practiced without these specific details. In other instances, well-known constructions or functions are not described in detail, so as not to obscure the present invention.

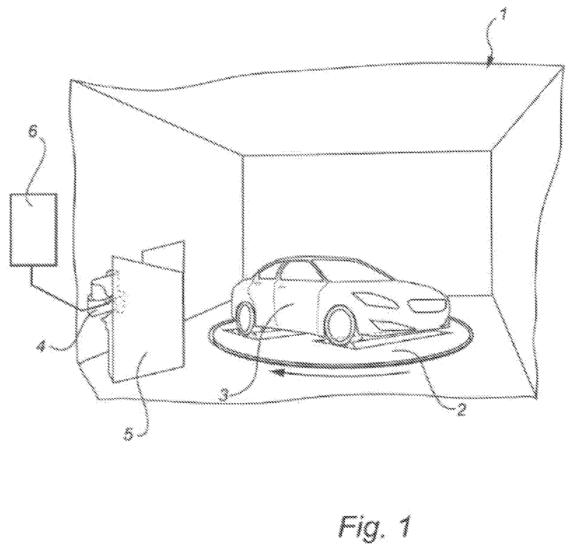

In a first embodiment, as illustrated in FIG. 1, the apparatus comprises a reverberation chamber (RC). The reverberation chamber 1 has walls of an inwardly reflective material, rendering the walls reflective to electromagnetic waves, thereby emulating a multi-path environment, and preferably a rich isotropic multipath (RIMP) environment. Thus, the internal chamber formed in the chamber is preferably completely shielded, having reflecting material, such as metal, on all walls and floor and ceiling. The floor of the chamber is inwardly reflective, but optionally covered with a top layer to resemble asphalt or other road covers.

Further, a rotatable platform 2 is provided within the chamber, and enclosed within the internal cavity. The platform is arranged to support and rotate a vehicle 3 on it, such as a car, a bus or any other type of vehicle. A device under test (DUT) is arranged in or on the vehicle. The device under test can e.g. be a communication device arranged within the car, and having an exteriorly mounted antenna. However, it may also be a communication device having an integrated antenna and being operated within the car, such as a mobile phone, a tablet PC, a computer or the like being operated within the car.

The rotatable platform is preferably capable of rotating the vehicle completely, i.e. 360°. The rotation may be controlled by a control PC, in same way as for the per se known platform stirring used in U.S. Pat. Nos. 7,444,264, 7,286,961 and WO 12/171562, so that rotation can be performed intermittently or continuously during measurement. Preferably, the platform also has means to allow the vehicle to be measured with the wheels rolling and the engine working. To this end, the platform may e.g. comprise rotatable rollers on which the wheels are supported. The chamber may be intended for measurements of cars only, but may also be for measurement on busses, as well as other types of vehicles. By rotation of the vehicle during measurement, either intermittently or continuously, it has been found that a very efficient stirring of the mode distribution is obtained within the chamber. Thus, there is in most cases no need for any additional mode stirrers, even though such additional mode stirrers may optionally be provided.

Further, at least one chamber antenna 4 is provided within internal cavity of the chamber, preferably at fixed position(s). For example, the antenna may be arranged on one or several of the walls of the internal cavity. The antenna may be an electric monopole, a helical antenna, a microstrip antenna or similar small antennas. For example, the antennas may be of any of the types disclosed in the above-discussed U.S. Pat. Nos. 7,444,264 and 7,286,961.

In a preferred embodiment, the antenna is of the type having orthogonal faces, similar to the one disclosed in WO 12/171562. In such an embodiment, the antenna(s) is arranged on an antenna holder comprising three surfaces of a reflective material, wherein the surfaces extend in planes which are orthogonal in relation to each other and each surface facing away from the other surfaces. These chamber antennas correspond to the so-called wall antennas in the previous U.S. Pat. Nos. 7,444,264 and 7,286,961, but are no longer required to be fixed to the walls, but rather fixed to an antenna holder located somewhere inside the chamber away from any wall. In another preferred alternative, the antenna is a multi-port butterfly antenna, e.g. similar to the one discussed in PCT/SE2013/051130. Using such or similar antennas provides a very useful polarization stirring, and also enables e.g. MIMO measurements. Preferably, the chamber antenna(s) is/are placed at a distance from the side walls, floor and roof of the chamber. Preferably this distance exceeds ½ wavelength from each wall, floor and roof of the chamber, of the frequency used for testing.

The apparatus may further comprise a shield 5, arranged to prevent a direct line-of-sight between a chamber antenna and the device under test, the shield preferably being of metal. The shield may e.g. be configured and arranged in a way similar to the shield discussed in WO 12/171562. Preferably, the shield is dimensioned so that direct coupling between the chamber antenna(s) and the device under test is strongly reduced, and at the same time, the shield does only insignificantly reduce the multimode distribution within the chamber. Still further, the shield preferably has a non-linear extension in the width direction, and preferably a curved or angled extension, whereby the shield partly surrounds the chamber antenna(s). The shield is preferably arranged at a distance from the chamber antenna(s), said distance corresponding to at least ½ wavelength used for testing.

A measuring instrument 6 is connected wirelessly to the device under test and via cables to the chamber antenna, for measuring the transmission between them, and thereby to measure one or several parameters related to the communication performance of the device under test. The measuring instrument may be arranged externally from the internal cavity, and connected to the internal cavity by means of a cable. The measurement instrument preferably comprises analyzing means, e.g. realized by dedicated software on a personal computer or the like, and can e.g. comprise a commercially available measuring instrument, such as a network analyzer or spectrum analyzer or similar, for determining the transmitted power between the antennas. Additionally or alternatively, the measuring instrument may comprise a base station emulator.

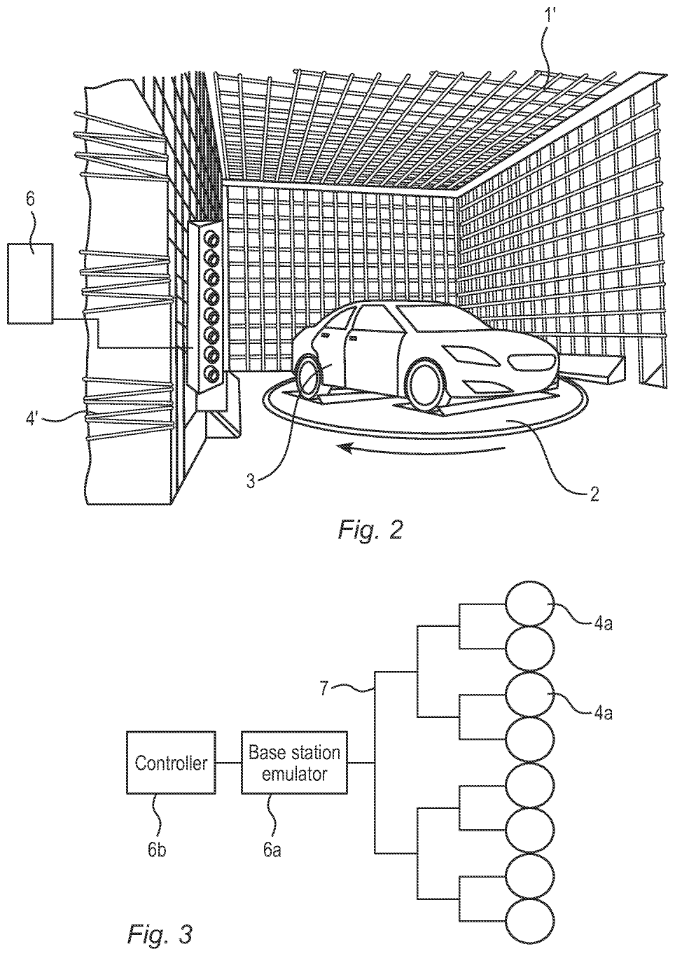

In another embodiment, illustrated in FIG. 2, the chamber is a random-LOS chamber 1′, having inwardly absorbing walls. The random-LOS chamber is essentially the same as in the previously discussed RC chamber, but this chamber has absorbers on the walls, as seen in FIG. 2. This chamber can be made approximately equally small as the RC chamber, or only to a small extent larger. The random-LOS chamber has absorbers on most, and preferably all walls, rendering the walls absorbing to electromagnetic waves, thereby simulating a random-LOS environment. The internal chamber formed in the chamber is preferably completely shielded, having reflecting material, such as metal, on all walls and floor and ceiling, and having absorbers being provided on all or most walls and ceiling, but not on the floor. The floor is preferably of metal (or conductive), but the metal can be covered with something to resemble a top layer of asphalt or other road covers.

The Random-LOS chamber is to a large extent similar to or the same as in the previously discussed RC chamber, and e.g. has a rotatable platform 2 for supporting a vehicle 3, being structured and operated in the same way as discussed above in relation to the RC chamber embodiment.

Further, a chamber antenna/measurement antenna 4′ is preferably arranged in the chamber, and is preferably arranged as a vertical linear array antenna. The vertical linear array antenna may be dual-polarized, or there may be two orthogonally polarized linear arrays located side-by-side, and e.g. arranged in one corner of the chamber or along a wall of the chamber. The vertical linear array comprises a plurality of antenna elements 4a, equidistantly arranged in a linear direction.

As best seen in FIG. 3, the apparatus further preferably comprises two branched distribution networks 7 connecting the vertical linear array elements for each polarization to each of two ports of the measuring instrument, here shown as a base station emulator 6a, and a controller 6b, such as a PC. The branched distribution/combination network preferably comprises a number of branched connections, separating the output/input from the base station emulator 6a into a number of equally fed inputs/outputs connected to the antenna elements 4a. In the illustrated example, the branched distribution/combination network has a first branched connection, separating the line into two, two second branched connections, separating the two lines into four, and four third branched connections, separating the four lines into eight. However, other branching arrangements, e.g. using branching into three, using more or fewer layers of branched connections, etc. are feasible. Such a fixed distribution arrangement is very efficient to provide a simple interface between the linear array and the base station emulator, and is also very cost-efficient.

The linear array 4′ preferably comprises a plurality of wideband array elements. The far field radiation pattern in the direction of the linear arrays is to a good approximation given by the common output of the elements of the array. Different far field directions in azimuth plane may be obtained by rotating the car. Further, the linear array may be tiltable to assume different tilt angles, in the elevation plane. For example, the linear array may be tiltable to assume angles in the range of 60°-90° in relation to the horizontal/floor plane, or in the range 70°-90°. The normal, untilted position would be 90 degrees, and less than 90° tilt corresponds to the linear array being tilted forward in the direction of the car. The height of the linear array may also be changed in order to find the best height for measuring the far field PoD. This optimum height will depend on the location of the antennas of the wireless device on the vehicle, and the height of the vehicle. The optimum height can be found by simulation as part of the detailed design of the measurement facility.

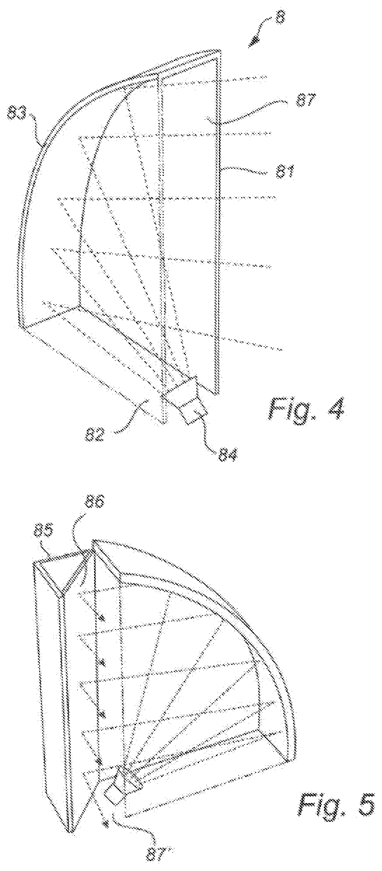

Alternatively, a pill-box style antenna 8 can be used. Such an antenna, as is schematically shown in FIGS. 4 and 5. This antenna preferably comprises two parallel plates 81, 82, preferably of metal, forming a cavity there between, and an elongated aperture 87 formed between the parallel plates 81, 82. A curved reflector 83 is arranged opposite the elongate aperture 87. The curved reflector is preferably arranged as a part of a cylindrical wall, and having the form of a parabolic arc. A feeding or reception device 84, such as a dipole antenna, a feed horn or the like, may be arranged to emit radiation towards the curved reflector, and/or receive radiation reflected by said curved reflector. The feeding or reception device may also be provided in the form of a rectangular waveguide or the like, debouching into the cavity formed between the parallel plates. The feeding or reception device is preferably located at the focal point of the parabolic reflective wall.

The elongated aperture may be arranged between the parallel plates, and be emitting radiation in a main direction essentially parallel to the plates, as is shown in FIG. 4. However, alternatively, the elongated aperture 87′ may be arranged in one of the side walls, or in an extension of one of the side walls, and consequently be emitting radiation in a main direction being essentially perpendicular to the this plate. Such an embodiment is illustrated in FIG. 5. A slanted additional wall 86 may further be provided to reflect radiation into and/or out of the cavity through the aperture. The antenna solution of FIG. 5 can be arranged more easily, and with less space requirement, than the antenna solution of FIG. 4. Any part of the exterior of the antenna, apart from the elongated aperture, exposed to the interior of the chamber is preferably covered with absorbent material.

The elongated aperture is preferably rectangular, and preferably of essentially the same overall dimensions, orientation and position in the chamber as the previously discussed linear array. The parallel plate waveguide preferably excites the aperture with a constant phase. To this end, the spacing between the two parallel plates is preferably less than a half wavelength. The elongate aperture may further be provided with longitudinal corrugations or grooves along its sides, preferably one or two on each side, in order to direct its radiation pattern towards the vehicle.

The dimensions of the reverberation chamber discussed above in relation to FIG. 1 can be held very limited, compared to conventional anechoic chambers for automotive applications, and the same. Further, the dimensions of the random-LOS chamber, discussed in relation to FIG. 2, can be equally small, or only slightly greater. The dimensions may be as low as only 1 m separation from the vehicle in all directions, i.e. the height of the largest vehicle for which the chamber is intended+1 m in the height direction, and the length of the largest vehicle for which the chamber is intended+2 m in the width and length direction. This is illustrated by the schematic arrows in FIGS. 1 and 2.

The above-discussed linear array antenna is particularly suited for the random LOS chamber, but may also be used in other types of chambers.

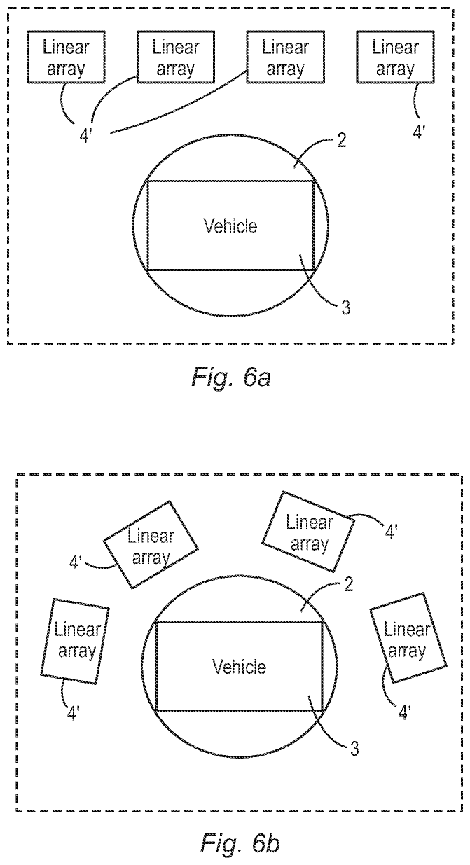

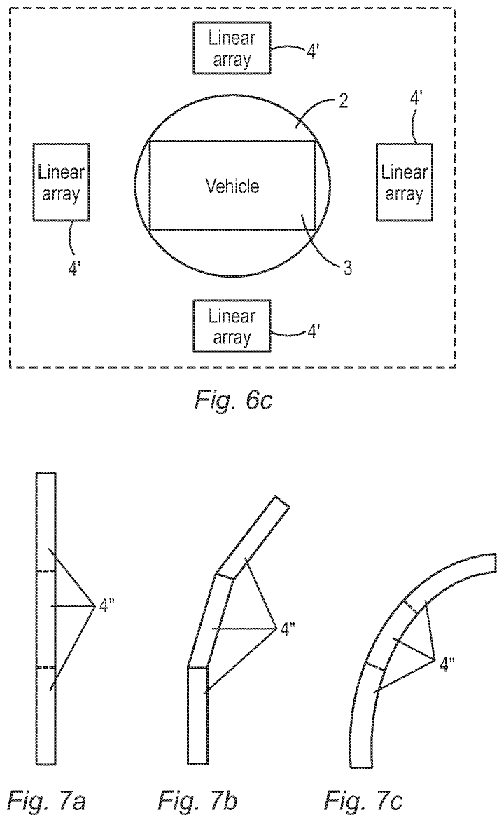

The chamber may be provided with more than one linear array antenna, or columns of linear array antennas. Such embodiments are illustrated in FIGS. 6a-6c. In these embodiments four linear array antennas 4′ are provided. However, two or three linear array antennas may be used instead, or more than four, such as five or six, or even more. The linear array antennas are preferably located on one side of the platform 2, as in the embodiments of FIGS. 6a and 6b. In the embodiment of FIG. 6a, the antennas are arranged along one side of the chamber (shown in dashed lines). In the embodiment, of FIG. 6b, the antennas are arranged along an arc or semicircle, extending along a part of the platform. However, the antennas may also be distributed evenly around the platform, as in the embodiment of FIG. 6c.

At least one of the linear array antennas may further be tilted to assume a different angle forward toward the platform than the other(s), thereby providing different elevation angles of the far field.

Further, the linear array antennas are preferably connected to one base station emulator or channel emulators by using a distribution network of cables and power dividers, but they can also be connected to different ones or to different ports on a common channel emulator, and in this case they are preferably distributed around the platform and individually calibrated.

Still further, the linear array antennas may be located at different azimuth angles around the platform.

Regardless of whether one or several linear array antennas are used, the linear array antenna(s) may advantageously comprise several sections. Various embodiments of such arrangements are illustrated in FIGS. 7a-7c, where FIG. 7a illustrates an embodiment having three sections arranged in a straight disposition atop of each other. FIG. 7b illustrates an embodiment in which the linear array assumes a curved disposition, where the sections are sequentially tilted towards the platform, thereby assuming a curved disposition. FIG. 7c illustrates another curved disposition, where the linear array antenna assumes the shape of an arc. Even though these examples show three sections, more or fewer sections may also be used.

To feed the different sections in the curved disposition, the distribution network preferably comprises fixed delay lines compensation for the non-straight extension of the linear array, preferably in such a way that the voltage received at the end of the distribution network is representative of a far-field radiation pattern of the antenna when embedded on the platform.

For calibration, a reference antenna (not shown) may further be provided in the chambers. The calibration for the tests in RC is done with the vehicle in the chambers, and the calibration antenna can e.g. be located on the roof of the car, or beside the car on the platform. The location of the reference antenna in the random-LOS case is preferably such that there is no blockage caused by the car, and is preferably done without the presence of the car. The calibration is done when the platform is rotated continuously or stepwise.

The invention has now been described with reference to specific embodiments. However, several variations of the communication system are feasible. For example, the chamber is preferably, out of practical reasons, of a rectangular shape. However, other shapes, which are easy to realize, may also be used, such as vertical walls with flat floor and ceiling and with a horizontal cross-section that forms a circle, ellipse or polygon. Further, the communication between the device under test and the chamber antenna/measurement antenna may be in either or both directions. Accordingly, each antenna may be arranged for either transmitting or receiving, or both. Further, even though the reverberation chamber and the random-LOS chamber have been described as two different chambers, it may also be possible to combine these chambers into one, e.g. by use of dismountable absorbing elements to cover the walls and ceiling when the chamber is to be used as a random-LOS chamber, and to be dismounted when the chamber is to be used as a reverberation chamber. Still further, the various features discussed in the foregoing may be combined in various ways. The embodiment of the random-LOS case describes a linear array antenna with a distribution/combination network. It is envisioned that this distribution network also may be realized digitally, by having DA/AD converters and transmitting/receiving amplifiers connected to each port of the linear array. Then, the amplitude and phase can be controlled digitally, so that the mechanical tilt of the linear array will be unnecessary. Such and other obvious modifications must be considered to be within the scope of the present invention, as it is defined by the appended claims. It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting to the claim. The word “comprising” does not exclude the presence of other elements or steps than those listed in the claim. The word “a” or “an” preceding an element does not exclude the presence of a plurality of such elements. Further, a single unit may perform the functions of several means recited in the claims.

1. An apparatus for measuring over-the-air (OTA) wireless communication performance in an automotive application of a device under test arranged on or in a vehicle, comprising: a chamber defining an internal cavity therein, and a platform for supporting the vehicle, wherein the chamber is a random-LOS chamber, having inwardly absorbing walls, and wherein the chamber is adapted to enclose the platform, wherein the platform is a rotatable platform that can rotate the vehicle, and wherein the floor of the chamber is inwardly reflective, and optionally covered with a top layer to resemble asphalt or other road covers, and further comprising at least one linear array antenna within the chamber.

2. The apparatus of claim 1, wherein the platform has means to allow the vehicle to be measured with the wheels rolling and the engine working.

3. The apparatus of claim 1, wherein the platform is arranged to be rotatable 360° continuously or intermittently during measurement.

4. (canceled)

5. (canceled)

6. (canceled)

7. (canceled)

8. (canceled)

9. (canceled)

10. (canceled)

11. The apparatus of claim 1, wherein the random-LOS chamber has absorbers on all walls, rendering the walls absorbing to electromagnetic waves, thereby simulating a random-LOS environment, at least one chamber antenna arranged in the cavity; and a measuring instrument connected to the device under test and the chamber antenna, for measuring the transmission between them.

12. The apparatus of claim 1, wherein the internal chamber formed in the chamber is completely shielded, having reflecting material behind the absorbers, such as metal, on all walls and floor and ceiling, and absorbers being provided on all or most walls and ceiling, but not on the floor.

13. The apparatus of claim 1, wherein at least one chamber antenna arranged in the chamber is a vertical linear array antenna.

14. The apparatus of claim 13, wherein the vertical linear array antenna is dual-polarized, and arranged in one corner of the chamber or along a wall of the chamber.

15. The apparatus of claim 13, further comprising a branched distribution network connecting the vertical linear array antenna to a base station emulator.

16. The apparatus of claim 13, wherein the linear array antenna is tiltable to assume different tilt angles in the elevation plane.

17. The apparatus of claim 1, wherein at least one chamber antenna arranged in the chamber is a pill-box style antenna, comprising two parallel plates, a curved reflecting wall between the two plates, and an elongated aperture opposite to the curved wall.

18. The apparatus of claim 1, wherein the height of the internal cavity is in the range of H+0.5 m and H+3 m, where H is the height of the highest vehicle on which the chamber is intended to measure.

19. The apparatus of claim 1, wherein the length and width of the internal cavity are both in the range of L+1.5 m and L+4 m, where L is the length of the longest vehicle on which the chamber is intended to measure.

20. The apparatus of claim 1, wherein it is adapted to measure at least one of the following communication performance parameters: total radiated power (TRP), total isotropic sensitivity (TIS), throughput, antenna efficiency, average fading sensitivity and diversity and MIMO gain.

21. (canceled)

22. The apparatus of claim 1, wherein at least one of the linear array antennas comprises several linear array sections arranged on top of each other.

23. The apparatus of claim 22, wherein the several linear array sections are arranged in a straight disposition.

24. The apparatus of claim 22, wherein the several linear array sections are arranged in a curved disposition, extending from the base in a direction towards the platform, and preferably extending at least partly over the platform.

25. The apparatus of claim 22, wherein two or more linear array antennas are provided, said linear array antennas being located on one side of the platform and combined by a distribution network of cables and power dividers.

26. The apparatus of claim 22, further comprising a distribution network for feeding the linear array.

27. The apparatus of claim 26, wherein the several linear array sections are arranged in a curved disposition, extending from the base in a direction towards the platform, and preferably extending at least partly over the platform, and wherein the distribution network comprises fixed delay lines compensation for the non-straight extension of the linear array, preferably in such a way that the voltage received at the end of the distribution network is representative of a far-field radiation pattern of the antenna when the platform rotates.

28. The apparatus of claim 22, wherein the linear array antennas are being tilted to assume different angles forward toward the platform, thereby providing different elevation angles of the far field.

29. The apparatus of claim 22, wherein linear array antennas are connected to the same port on a base station emulator or channel emulator via a distribution network with cables and power dividers between them.

30. The apparatus of claim 22, wherein at least two linear array antennas are provided, the linear array antennas being located at one side of the platform.

31. The apparatus of claim 22, wherein at least two linear array antennas are provided, the linear array antennas being distributed around the platform, and preferably being evenly distributed around the platform.

32. A method for measuring over-the-air (OTA) wireless communication performance in an automotive application of a device under test arranged on or in a vehicle, comprising:
providing a chamber defining an internal cavity therein, wherein the chamber is a random-LOS chamber, having inwardly absorbing walls, and wherein the floor of the chamber is inwardly reflective, and optionally covered with a top layer to resemble asphalt or other road covers, and further comprising at least one linear array antenna within the chamber;
arranging the vehicle within the internal cavity; and
measuring over-the-air wireless communication performance while horizontally rotating the vehicle intermittently or continuously during the measuring.

33. The method of claim 32, further comprising operating the vehicle so that the wheels are rolling and the engine is working during said measuring.

34. The method of claim 32, wherein the vehicle is rotated over 360° during measurement.

35. (canceled)

36. (canceled)
